(19) United States
(12) Patent Application Publication
(10) Pub. No.: US 2002/0113627 A1
(43) Pub. Date: Aug. 22, 2002

(54) Input buffer circuit capable of suppressing fluctuation in output signal and reducing power consumption

(75) Inventor: Hironori Iga, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 09/940,621

(22) Filed: Aug. 29, 2001

(30) Foreign Application Priority Data
Feb. 22, 2001 (JP) 2001-046277 (P)

(51) Int. Cl. H03B 1/00

(52) U.S. Cl. 327/108

(57) ABSTRACT

A coupled circuit is connected between a differential amplifier circuit and an inverter. The coupled circuit supplies to an output node a constant potential equal to a logic threshold value of the inverter. When a direct-current component and an amplitude of an output signal output from the differential amplifier circuit fluctuate due to fluctuations of a direct-current component and an amplitude of an input signal, the direct-current component and the amplitude are approximated to the constant potential applied to the node in the coupled circuit and then output. Thus, the present input buffer is capable of achieving reduction in power consumption and suppresses fluctuation of an output signal in relation to fluctuations in the direct-current component and the amplitude of an input signal.

### BACKGROUND OF THE INVENTION

1. Field of the Invention

The present invention relates to an input buffer circuit, and more specifically, to an input buffer circuit included in a semiconductor device.

2. Description of the Background Art

An input buffer circuit of a semiconductor memory device is for converting an externally input signal into a potential suitable for use inside the semiconductor memory device.

FIG. 9 is a circuit diagram of an input buffer circuit.

As shown in FIG. 9, an input buffer circuit 10 includes a differential amplifier circuit 1 for comparing a reference potential Vref with an input signal Vin and an inverter 2 for receiving an output signal Vout from differential amplifier circuit 1 and inverting the received signal.

Differential amplifier circuit 1 includes N-channel MOS transistors 3 to 5 and P-channel MOS transistors 6 and 7. The respective sources of P-channel MOS transistors 6 and 7 are both connected to a power-supply node VCC. In addition, the gates of P-channel MOS transistors 6 and 7 are connected to one another, and P-channel MOS transistor 6 is diode-connected.

A drain of N-channel MOS transistor 4 is connected to a drain of P-channel MOS transistor 6, and a drain of N-channel MOS transistor 5 is connected to a drain of P-channel MOS transistor 7, respectively. The respective sources of N-channel MOS transistors 4 and 5 are both connected to a drain of N-channel MOS transistor 3. Reference potential Vref is input to a gate of N-channel MOS transistor 4, and input signal Vin is input to a gate of N-channel MOS transistor 5, respectively. Output signal Vout is output from an output node A1 which is a point where N-channel MOS transistor 5 and P-channel MOS transistor 7 are connected.

Moreover, a source of N-channel MOS transistor 3 is connected to a ground node 500. Since a constant potential is supplied to a gate of N-channel MOS transistor 3, a current i that flows through N-channel MOS transistor 3 is always constant.

Inverter 2 includes a P-channel MOS transistor 8 and an N-channel MOS transistor 9 connected in series between a power-supply node VCC and a ground node 500 for receiving at their respective gates output signal Vout. Inverter 2 receives output signal Vout and outputs a signal φB from an output node A2 which is a point where P-channel MOS transistor 8 and N-channel MOS transistor 9 are connected.

Differential amplifier circuit 1 compares input signal Vin with reference potential Vref, and outputs an L-level output signal Vout when the level of input signal Vin is higher than that of reference potential Vref, and outputs an H-level output signal Vout when the level of input signal Vin is lower than that of reference potential Vref.

Now, an operation of input buffer circuit 10 having such circuit arrangement as described above will be described.

FIG. 10 is an operation waveform chart showing an input signal Vin1, an output signal Vout1, and a signal φB1.

As shown in FIG. 10, when input signal Vin1, whose direct-current component is V1 which is equal to reference potential Vref, is input to input buffer circuit 10, output signal Vout1 having a phase reverse to that of input signal Vin1 is output from output node A1 of differential amplifier circuit 1 in input buffer circuit 10. At this time, differential amplifier circuit 1 is designed such that the direct-current component of output signal Vout1 equals a threshold voltage Vth1 of inverter 2. As a result, inverter 2 receives output signal Vout1 and outputs signal φB1 having a phase reverse to that of output signal Vout1.

In addition, since N-channel MOS transistor 3 of differential amplifier circuit 1 functions as a constant current source, a direct-current component Vth1 of output signal Vout1 output from output node A1 would always be constant even when direct-current component V1 of input signal Vin1 and reference potential Vref input to differential amplifier circuit 1 fluctuate in common phase.

In this manner, in a conventional input buffer circuit, since N-channel MOS transistor 3 in differential amplifier circuit 1 shown in FIG. 9 acts as a constant current source, it is possible to output the output signal Vout1 having a stable direct-current component Vth1 that is independent of the common phase fluctuation of direct-current component V1 of input signal Vin1 and reference potential Vref input to differential amplifier circuit 1.

In differential amplifier circuit 1 having such current arrangement, the potential levels of input signal Vin and reference potential Vref should be set high as a voltage drop caused by N-channel MOS transistor 3 is taken into account. Thus, in order to achieve low power consumption as required of the semiconductor memory devices in recent years, it is desirable that differential amplifier circuit 1 does not include N-channel MOS transistor 3 as a constant current source.

If, however, N-channel MOS transistor 3 that functions as the constant current source is not provided in differential amplifier circuit 1, direct-current component Vth1 of output signal Vout1 from differential amplifier circuit 1 would fluctuate when direct-current component V1 of input signal Vin1 and reference potential Vref are input in common phase to differential amplifier circuit 1.

FIG. 11 is a circuit diagram of an input buffer circuit including a differential amplifier circuit lacking a constant current source. Moreover, FIG. 12 is a graph showing a static characteristic of an N-channel MOS transistor and a dynamic characteristic of a P-channel MOS transistor in the differential amplifier circuit shown in FIG. 11.

Referring to FIG. 11, a differential amplifier circuit 50 lacks N-channel MOS transistor 3 that functions as a constant current source as compared to differential amplifier circuit 1 shown in FIG. 9.

The circuit arrangement of an inverter 2 is the same as that shown in FIG. 9 so that the description will not be repeated.

Here, attention is called to direct-current component V1 of input signal Vin1 and reference potential Vref as the case will be described where direct-current component V1 and reference potential Vref fluctuate in common phase.

When direct-current component V1 of input signal Vin1 and reference potential Vref fluctuate in common phase, N-channel MOS transistors 4 and 5 in differential amplifier circuit 50 follow the static characteristic of the N-channel MOS transistor shown in FIG. 12, while P-channel MOS transistors 6 and 7 follow the dynamic characteristic of the P-channel MOS transistor shown in FIG. 12. Consequently, a value at the point of intersection of both characteristics becomes equal to output signal Vout output from a node A1 of differential amplifier circuit 50 and a gate potential of P-channel MOS transistors applied to a node A4.

When direct-current component V1 and reference potential Vref rise in common phase, the statistic characteristic of N-channel MOS transistors rises from statistic characteristic 1 to statistic characteristic 2. Thus, output signal Vout and the gate potential of P-channel MOS transistors drop from V10 to V20.

Thus, in differential amplifier circuit 50 lacking N-channel MOS transistor 3 that functions as a constant current source, output signal Vout would fluctuate when direct-current component V1 and reference potential Vref that are input fluctuate in common phase.

Now, the influence of the fluctuation in direct-current component V1 of input signal Vin1 on a signal φB1 will be described.

FIGS. 13 to 15 are operation waveform charts showing the fluctuations of output signal Vout1 and signal φB1 when direct-current component V1 of input signal Vin1 input to differential amplifier circuit 50 in an input buffer circuit 11 fluctuates.

As shown in FIG. 13, when direct-current component V1 of input signal Vin1 and reference potential Vref input to differential amplifier circuit 50 both rise to V2, an output signal Vout2 is output from output node A1 as shown in FIG. 14. A direct-current component Vth2 of output signal Vout2 is smaller than a direct-current component Vth1 of output signal Vout1.

Consequently, a time tb at which output signal Vout2 becomes equal to a threshold voltage Vth1 of inverter 2 as output signal Vout2 rises from the logic low or L level to the logic high or H level comes later than a time ta at which output signal Vout1 becomes equal to threshold voltage Vth1 as output signal Vout1 rises from the L level to the H level.

As a result, the waveform of a signal φB2 output from inverter 2 having received output signal Vout2 would be as shown in FIG. 15, and a time t2 at which signal φB2 switches from the H level to the L level comes later than a time t1 at which signal φB1 switches from the H level to the L level.

When both direct-current component V1 of input signal Vin1 and reference potential Vref shown in FIG. 13 drop to V3, an output signal Vout3 as shown in FIG. 14 is output from output node A1 of differential amplifier circuit 50. A direct-current component Vth3 of output signal Vout3 is greater than direct-current component Vth1 of output signal Vout1.

Consequently, a time tc at which output signal Vout3 becomes equal to threshold voltage Vth1 of inverter 2 as output signal Vout3 rises from the L level to the H level comes earlier than time ta at which output signal Vout1 becomes equal to threshold voltage Vth1 as output signal Vout1 rises from the L level to the H level.

As a result, the waveform of a signal φB3 output from inverter 2 having received output signal Vout3 would be as shown in FIG. 15, and a time t3 at which signal φB3 switches from the H level to the L level comes earlier than time t1 at which signal φB1 switches from the H level to the L level.

As a result of the above-described operation, when direct-current component V1 of input signal Vin1 and reference potential Vref fluctuate in common phase, the timing at which signal φB1 of input buffer circuit 11 switches from the H level to the L level and the timing at which signal φB1 switches from the L level to the H level would be shifted in time so that input buffer circuit 11 would not operate properly.

In addition, an output signal Vout output from a differential amplifier circuit is influenced by the fluctuation in the amplitude of an input signal Vin.

The influence of the fluctuation in the amplitude of input signal Vin1 on signal φB1 will be described below.

FIG. 16 is an operation waveform chart showing the fluctuation in the amplitude of input signal Vin1. Moreover, FIG. 17 is an operation waveform chart of an output signal Vout output in relation to the fluctuation in the amplitude of input signal Vin of FIG. 16.

As shown in FIG. 16, when direct-current component V1 of input signal Vin1 remains the same but the amplitude of input signal Vin1 alone increases, resulting in an input signal Vin4, an output signal Vout4 shown in FIG. 17 is output from differential amplifier circuit 50. Due to the characteristics of the transistors in differential amplifier circuit 50, the waveform of output signal Vout4 becomes distorted, and as a result, the time at which output signal Vout4 becomes equal to threshold voltage Vth1 of inverter 2 as output signal Vout4 rises from the L level to the H level shifts from the time at which output signal Vout1 becomes equal to threshold voltage Vth1 as output signal Vout1 rises from the L level to the H level.

On the other hand, when the amplitude alone of input signal Vin1 decreases, resulting in an input signal Vin5, an output signal Vout5 shown in FIG. 17 is output from differential amplifier circuit 50. Due to the characteristics of the transistors, almost no shift occurs in the timing at which the signal switches from the L level to the H level when the amplitude decreases so that the time at which output signal Vout5 becomes equal to threshold voltage Vth1 of inverter 2 as output signal Vout5 rises from the L level to the H level would become substantially the same as the time at which output signal Vout1 becomes equal to threshold voltage Vth1 as output signal Vout1 rises from the L level to the H level.

As seen from the above, when the amplitude of an input signal Vin input to differential amplifier circuit 50 increases, the timing at which signal φB output from inverter 2 switches from the H level to the L level and the timing at which signal φB switches from the L level to the H level would shift so that input buffer circuit 11 would not operate properly.

### SUMMARY OF THE INVENTION

The object of the present invention is to provide an input buffer circuit that is capable of achieving reduction in power consumption and that suppresses fluctuation of an output signal in relation to fluctuations in a direct-current component and an amplitude of an input signal.

An input buffer circuit according to the present invention includes a differential amplifier circuit for comparing a potential of an input signal input to a first differential input node with a reference potential input to a second differential input node and for outputting an output signal from an output node, an inverter, and a coupled circuit for approximating a potential level of a direct-current component of an output signal output from an output node of the differential amplifier circuit to a logic threshold value of the inverter and for outputting the output signal to the inverter.

Thus, it becomes possible to suppress fluctuation of an output signal in relation to fluctuation of a direct-current component of an input signal.

Preferably, the coupled circuit further decreases the amplitude of an output signal output from an output node of the differential amplifier circuit and outputs the output signal to the inverter.

Thus, it becomes possible to suppress fluctuation of an output signal in relation to an increase in the amplitude of an input signal.

More preferably, the coupled circuit includes a constant potential generating circuit for generating a constant potential and supplying the constant potential to an output node of the differential amplifier circuit.

More preferably, the constant potential generating circuit includes a first transistor connected between an output node of the differential amplifier circuit and a power-supply node, and a second transistor connected between an output node of the differential amplifier circuit and a ground node.

More preferably, substantially equal potentials are supplied to gates of the first transistor and the second transistor.

Consequently, the input buffer circuit does not depend on fluctuations of the direct-current component and the amplitude of an input signal.

More preferably, gates of the first transistor and the second transistor are connected to an output node of the differential amplifier circuit.

Thus, the input buffer circuit can dynamically deal with fluctuations of the direct-current component and the amplitude of the input signal.

An input buffer circuit according to the present invention includes a first coupled circuit for approximating a potential level of a direct-current component of an input signal to a prescribed potential level and for outputting the input signal, a second coupled circuit for approximating a potential level of a direct-current component of a reference potential to a prescribed potential level and for outputting the reference potential, and a differential amplifier circuit for comparing a potential of an input signal output from the first coupled circuit and input to a first differential input node with a reference potential output from the second coupled circuit and input to a second differential input node and for outputting an output signal from an output node.

Thus, it becomes possible to suppress fluctuation of an output signal in relation to fluctuation of a direct-current component of an input signal and fluctuation of a reference potential.

Preferably, the first coupled circuit further decreases an amplitude of the input signal and outputs the input signal to a first differential input node of the differential amplifier circuit, and the second coupled circuit further decreases an amplitude of the reference potential and outputs the reference potential to a second differential input node of the differential amplifier circuit.

Thus, it becomes possible to suppress fluctuation of an output signal in relation to an increase in the amplitude of an input signal.

More preferably, the input buffer circuit includes a first inverting amplifier circuit for amplifying the input signal and outputting the amplified signal to the first coupled circuit, and a second inverting amplifier circuit for amplifying the reference potential and outputting the amplified reference potential to the second coupled circuit.

Thus, it becomes possible to increase the operation speed of the differential amplifier circuit in the input buffer circuit.

More preferably, the first coupled circuit includes a first constant potential generating circuit for generating a first constant potential and supplying the first constant potential to a first differential input node of the differential amplifier circuit, and the second coupled circuit includes a second constant potential generating circuit for generating a second constant potential and supplying the second constant potential to a second differential input node of the differential amplifier circuit.

More preferably, the first constant potential generating circuit includes a first transistor connected between a first differential input node of the differential amplifier circuit and a power-supply node, and a second transistor connected between the first differential input node of the differential amplifier circuit and a ground node, and the second constant potential generating circuit includes a third transistor connected between a second differential input node of the differential amplifier circuit and a power-supply node, and a fourth transistor connected between the second differential input node of the differential amplifier circuit and a ground node.

More preferably, substantially equal potentials are supplied to gates of the first to fourth transistors.

Thus, the input buffer circuit does not depend on fluctuation of the direct-current component and the amplitude of an input signal.

More preferably, gates of the first transistor and the second transistor are connected to the first differential input node of the differential amplifier circuit, and gates of the third transistor and the fourth transistor are connected to the second differential input node of the differential amplifier circuit.

Thus, the input buffer circuit can dynamically deal with fluctuations of the direct-current component and the amplitude of the input signal.

According to the present invention, it becomes possible to provide a semiconductor memory device including an input buffer circuit that is capable of achieving reduction in power consumption and that suppresses fluctuation of an output signal in relation to fluctuations in the direct-current component and the amplitude of an input signal.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block schematic diagram representing an overall arrangement of a semiconductor memory device including an input buffer circuit according to an embodiment of the present invention.

FIG. 2 is a circuit diagram of an input buffer circuit 101 shown in FIG. 1.

FIG. 3 is an operation waveform chart of a signal output from a coupled circuit in FIG. 2.

FIG. 4 is an operation waveform chart of a signal output from an inverter in FIG. 2.

FIG. 5 is a circuit diagram of an input buffer circuit according to a second embodiment of the present invention.

FIG. 6 is a circuit diagram of an input buffer circuit 103 according to a third embodiment of the present invention.

FIG. 7 is a circuit diagram of a VTT generating circuit 65 shown in FIG. 6.

FIG. 8 is a circuit diagram of an input buffer circuit 104 according to a fourth embodiment of the present invention.

FIG. 9 is a circuit diagram of a conventional input buffer circuit.

FIG. 10 is an operation waveform chart showing an input signal Vin1, an output signal Vout1, and a signal φB1.

FIG. 11 is a circuit diagram of an input buffer circuit including a differential amplifier circuit lacking a constant current source.

FIG. 12 is a graph showing a static characteristic of an N-channel MOS transistor and a dynamic characteristic of a P-channel MOS transistor in the differential amplifier circuit shown in FIG. 11.

FIG. 13 is an operation waveform chart showing fluctuations of output signal Vout1 and signal φB1 when a direct-current component V1 of input signal Vin1 input to the differential amplifier circuit of the input buffer circuit shown in FIG. 11 fluctuates.

FIG. 14 is an operation waveform chart showing fluctuation of output signal Vout1 when direct-current component V1 of input signal Vin1 input to the differential amplifier circuit of the input buffer circuit shown in FIG. 11 fluctuates.

FIG. 15 is an operation waveform chart showing fluctuation of signal φB1 when direct-current component V1 of input signal Vin1 input to the differential amplifier circuit of the input buffer circuit shown in FIG. 11 fluctuates.

FIG. 16 is an operation waveform chart showing fluctuation in an amplitude of input signal Vin1.

FIG. 17 is an operation waveform chart of an output signal Vout output in relation to fluctuation in the amplitude of input signal Vin of FIG. 16.

### DESCRIPTION OF THE PREFERRED EMBODIMENTS

The embodiments of the present invention will be described in detail below with reference to the drawings. Throughout the drawings, the same or corresponding parts will be denoted by the same reference characters, and the descriptions thereof will not be repeated.

### FIRST EMBODIMENT

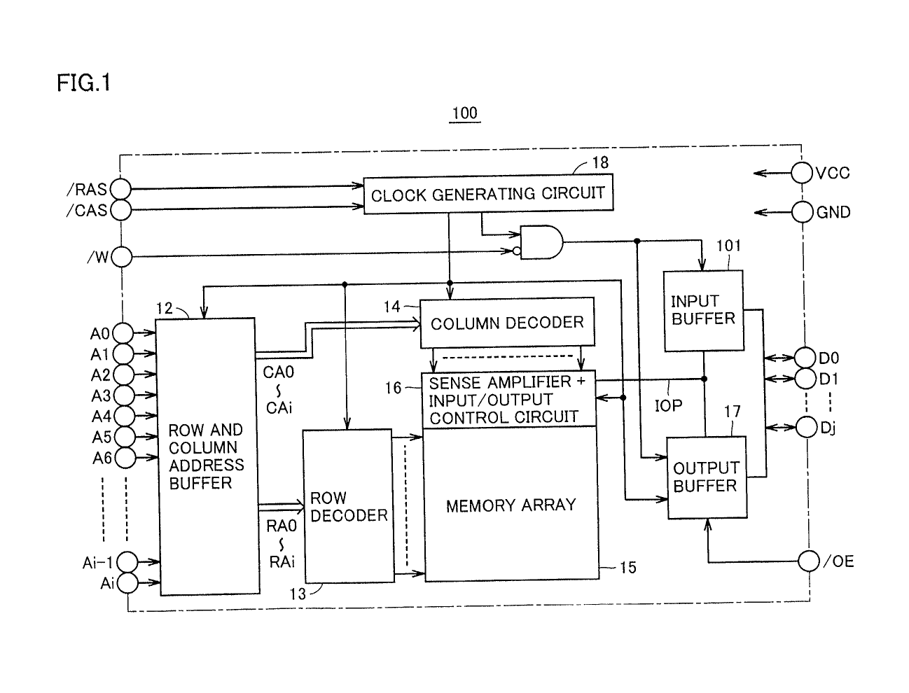

FIG. 1 is a block schematic diagram representing an overall arrangement of a semiconductor memory device including an input buffer circuit according to an embodiment of the present invention.

As shown in FIG. 1, a semiconductor memory device 100 includes a clock generating circuit 18, a row and column address buffer 12, a row decoder 13, a column decoder 14, a memory cell array 15, a sense amplifier+input/output control circuit 16, an input buffer circuit 101, and an output buffer 17.

Clock generating circuit 18 selects a prescribed operation mode according to external control signals /RAS and /CAS and controls the entire semiconductor memory device 100.

Row and column address buffer 12 generates row address signals RA0 to RAi and column address signals CA0 to CAi according to external address signals A0 to Ai (where i is an integer greater than or equal to 0) and supplies the generated row address signals RA0 to RAi and column address signals CA0 to CAi respectively to row decoder 13 and column decoder 14.

Memory cell array 15 includes a plurality of memory cells, each of which storing one bit of data. Each memory cell is arranged at a prescribed address determined by a row address and a column address.

Row decoder 13 designates a row address of memory cell array 15 according to row address signals RA0 to RAi provided from row and column address buffer 12. Column decoder 14 designates a column address of memory cell array 15 according to column address signals CA0 to CAi provided from row and column address buffer 12.

Sense amplifier+input/output control circuit 16 connects a memory cell of an address designated by row decoder 13 and column decoder 14 to one end of a data input/output line pair IOP. The other end of data input/output line pair IOP is connected to input buffer circuit 101 and output buffer 17.

During a write mode, in response to an external control signal /W, input buffer circuit 101 supplies data D0 to Dj (where j is an integer greater than or equal to 0) input from outside to the selected memory cell via data input/output line pair IOP.

During a read mode, in response to an external control signal /OE, output buffer 17 outputs read data from the selected memory cell to outside.

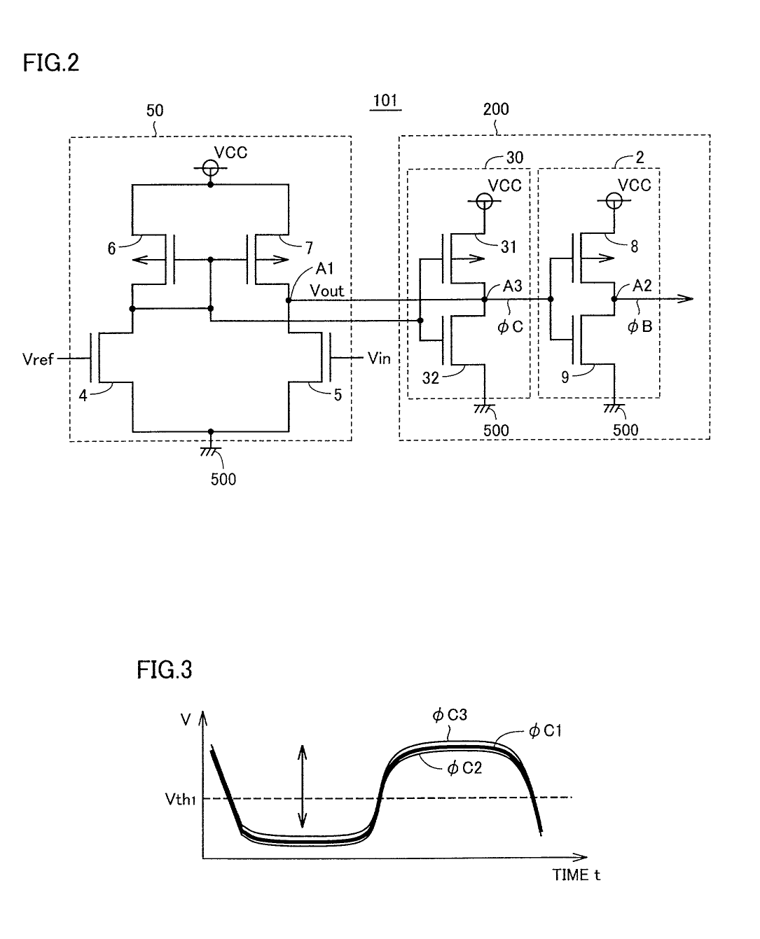

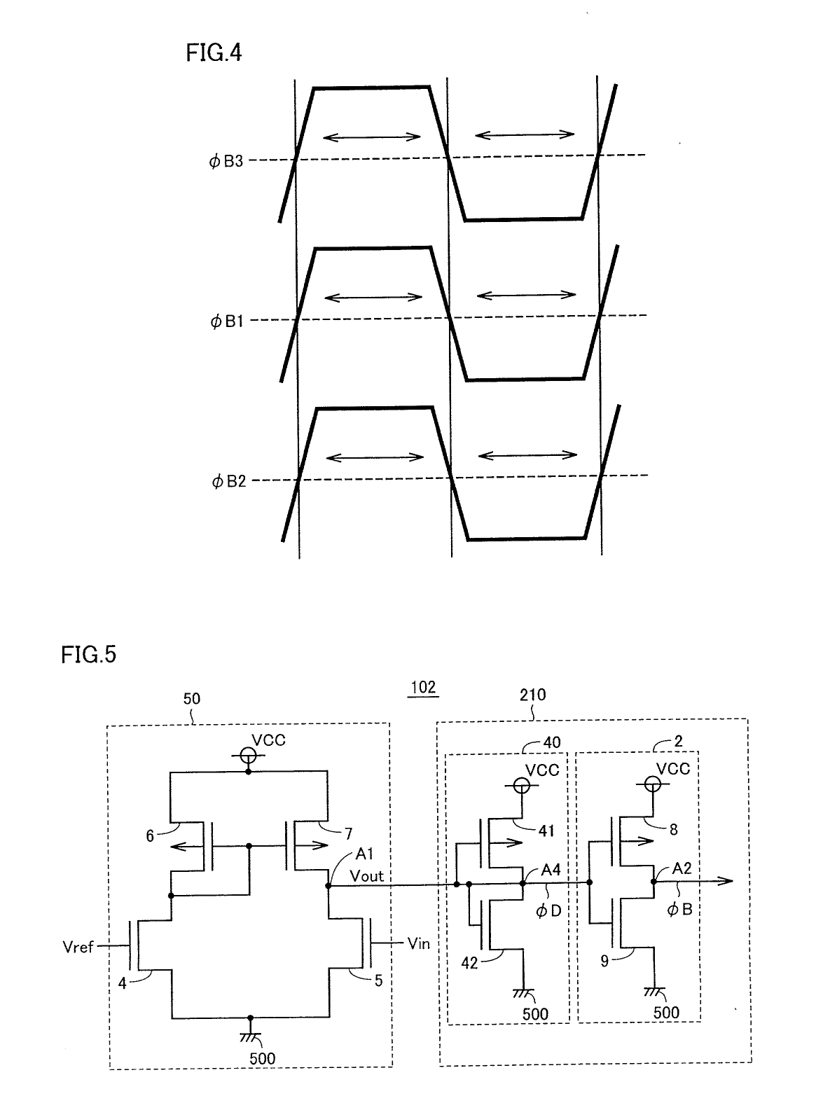

FIG. 2 is a circuit diagram of input buffer circuit 101 shown in FIG. 1.

As shown in FIG. 2, input buffer circuit 101 includes a differential amplifier circuit 50 and a control circuit 200. Control circuit 200 includes an inverter 2 and coupled circuit 30.

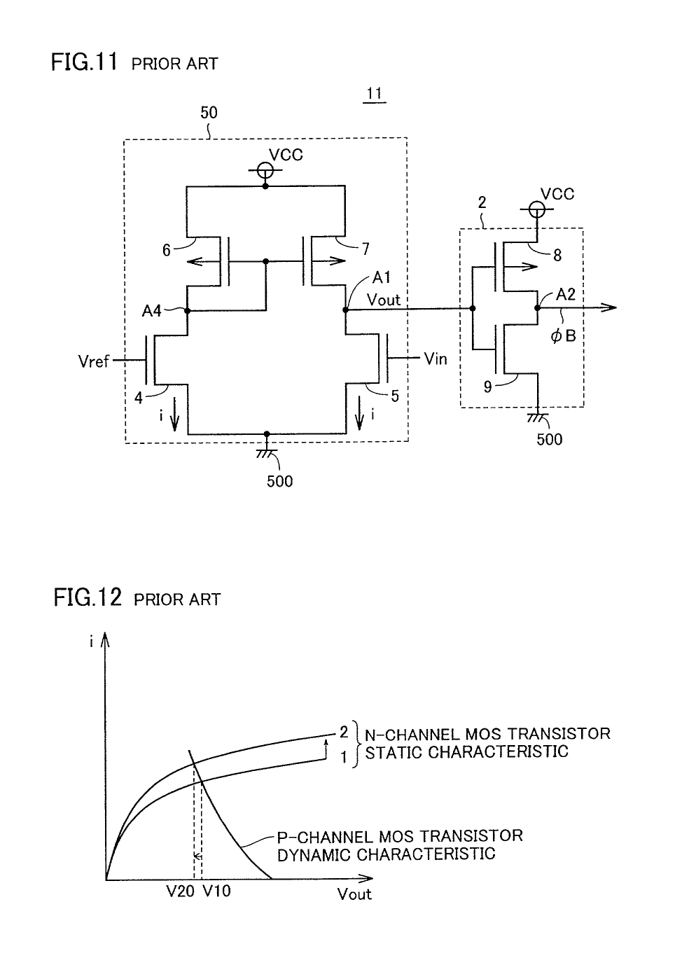

The circuit arrangements of differential amplifier circuit 50 and inverter 2 are the same as those in input buffer circuit 10 shown in FIG. 11 so that the description thereof will not be repeated.

Coupled circuit 30 includes a P-channel MOS transistor 31 and an N-channel MOS transistor 32 connected in series between a power-supply node VCC and a ground node 500. The gates of P-channel MOS transistor 31 and N-channel MOS transistor 32 are both connected to gates of N-channel MOS transistors 6 and 7 in differential amplifier circuit 50. In addition, an output node A3, which is a point where between P-channel MOS transistor 31 and N-channel MOS transistor 32 are connected, is connected to an output node A1 of differential amplifier circuit 50. Output node A3 is connected to gates of a P-channel MOS transistor 8 and an N-channel MOS transistor 9 in inverter 2.

The threshold voltage of coupled circuit 30 is set to be equal to the threshold voltage of inverter 2.

An operation of coupled circuit 30 in a case where a direct-current component of an input signal Vin and reference potential Vref fluctuate in common phase in input buffer circuit 101 having the above-described circuit arrangement will first be described.

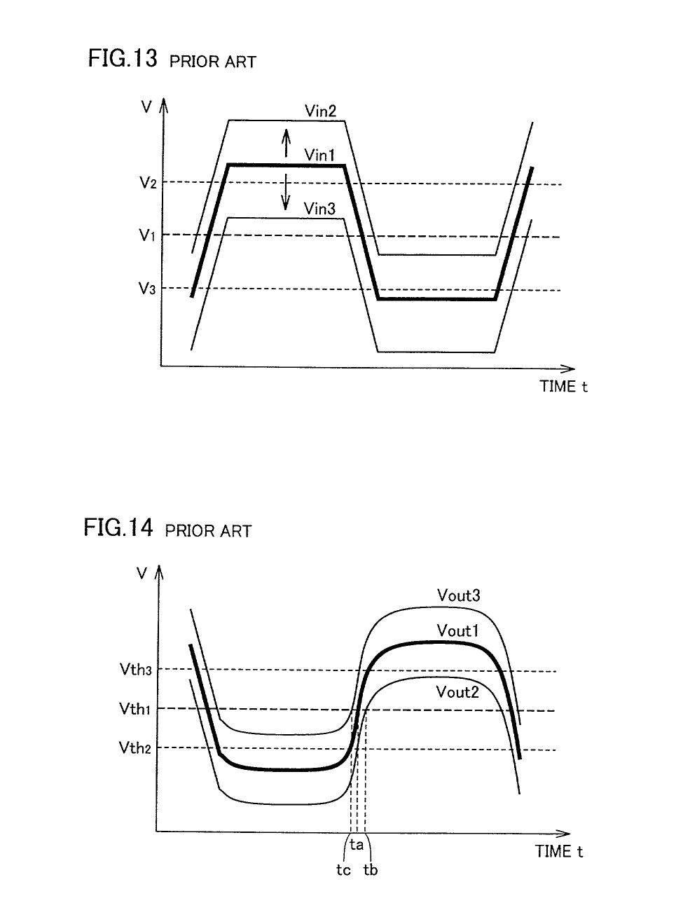

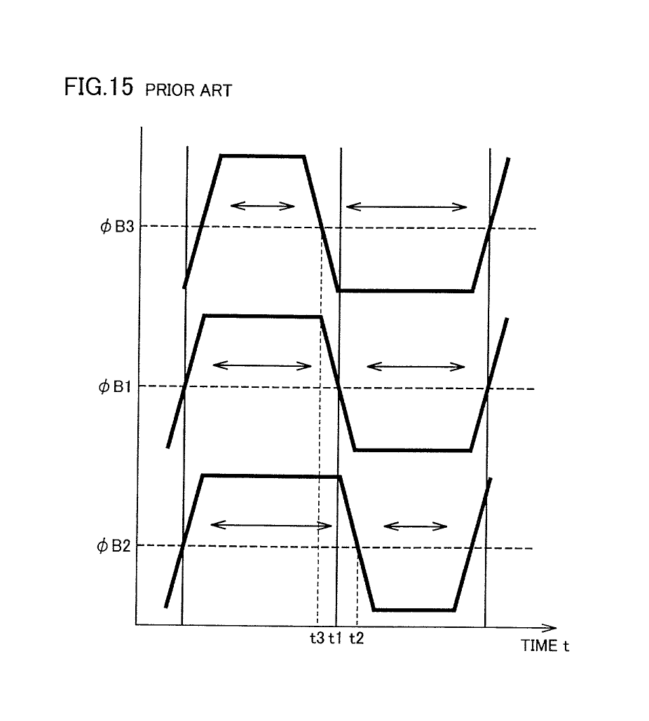

As shown in FIG. 13, as a result of direct-current component V1 of input signal Vin1 and reference potential Vref input to differential amplifier circuit 50 rising to V2, an input signal Vin2 is input to a gate of N-channel MOS transistor 5, and when a reference potential Vref having a phase that is common to that of a direct-current component V2 of input signal Vin2 is input to differential amplifier circuit 50, an output signal Vout2, whose direct-current component becomes a potential Vth2 which is lower than a threshold Vth1 of inverter 2 and coupled circuit 30, is output from output node A1.

A common gate potential of N-channel MOS transistors 6 and 7 forming a current mirror in differential amplifier circuit 50 is supplied to the respective gates of P-channel MOS transistor 31 and N-channel MOS transistor 32 in coupled circuit 30. The common gate potential is a constant potential so that threshold voltage Vth1 that equals the threshold voltage of inverter 2 is applied to an output node A3 of coupled circuit 30 at all times.

Therefore, when output signal Vout2 output from differential amplifier circuit 50 passes through output node A3 of coupled circuit 30, a direct-current component Vth2 of output signal Vout2 rises to become equal to threshold voltage Vth1. Consequently, a direct-current component of a signal φC2 output from coupled circuit 30 would become substantially equal to a direct-current component Vth1 of a signal φC1 output from coupled circuit 30 as a result of input signal Vin1 being input to differential amplifier circuit 50.

As a result, as compared with signal φB1 output from inverter 2 when input buffer circuit 101 receives input signal Vin1 at differential amplifier circuit 50, the shift in the timing at which signal φB2, which is output from inverter 2 when input buffer circuit 101 receives input signal Vin2 at differential amplifier circuit 50, switches from the H level to the L level and the shift in the timing at which signal φB2 switches from the L level to the H level are eliminated.

In the case where an input signal Vin3, whose direct-current component is V3 which is lower than V1, is input to differential amplifier circuit 50, and an output signal Vout3 is output from an output node as a result, like the case of output signal Vout2, a direct-current component of a signal φC3 obtained as a result of output signal Vout3 passing through coupled circuit 30 becomes equal to potential Vth1 of the direct-current component of signal φC1.

Thus, as compared with signal φB1 output from inverter 2 when input buffer circuit 101 receives input signal Vin1 at differential amplifier circuit 50, the shift in the timing at which signal φB3, which is output from inverter 2 when input buffer circuit 101 receives input signal Vin3 at differential amplifier circuit 50, switches from the H level to the L level and the shift in the timing at which signal φB3 switches from the L level to the H level are eliminated.

Now, in input buffer circuit 101 shown in FIG. 2, the operation of coupled circuit 30 when the amplitude of an input signal Vin fluctuates will be described.

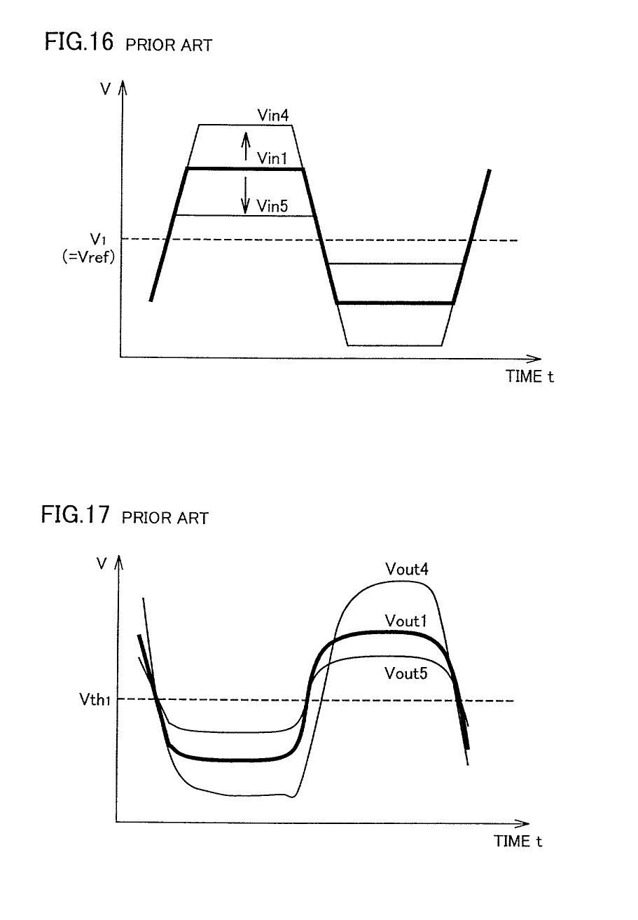

As shown in FIG. 16, when the amplitude of input signal Vin1 is amplified, resulting in an input signal Vin4, and when input signal Vin4 is input to differential amplifier circuit 50, an output signal Vout4 having a distorted operation waveform as shown in FIG. 17 is output from output node A1 of differential amplifier circuit 50.

A common gate potential of N-channel MOS transistors 6 and 7 forming a current mirror in differential amplifier circuit 50 is supplied to the respective gates of P-channel MOS transistor 31 and N-channel MOS transistor 32 in coupled circuit 30. The common gate potential is a constant potential so that a potential Vth1 is applied to output node A3 of coupled circuit 30 at all times.

Thus, when output signal Vout4 passes through output node A3 of coupled circuit 30, the amplitude of output signal Vout4 decreases, approaching threshold voltage Vth1.

Similarly, in the case where the amplitude of input signal Vin1 input to differential amplifier circuit 50 is decreased, resulting in an input signal Vin5 which is input and an output signal Vout5 is output, and when output signal Vout5 passes through output node A3 of coupled circuit 30, the amplitude of output signal Vout5 decreases, approaching threshold voltage Vth1.

Due to the transistor characteristics of the inverter, the smaller the fluctuation of the amplitude of the input signal, the smaller the shift in the timing at which the signal switches from the H level to the L level and the shift in the timing at which the signal switches from the L level to the H level become.

Thus, a signal φB output from inverter 2 is not influenced by the fluctuation of the amplitude of an input signal Vin1.

According to the above-described operation, in a case where the direct-current component and the amplitude of input signal Vin input to differential amplifier circuit 50 fluctuate, when output signal Vout is input to coupled circuit 30, a signal φC whose direct-current component being substantially equal to a threshold Vth and whose amplitude decreased would be output.

Consequently, when the direct-current component and the amplitude of input signal Vin fluctuate, signal φB output from inverter 2 is not influenced by such fluctuations, and the shift in the timing at which signal φB switches from the H level to the L level and the shift in the timing at which signal φB switches from the L level to the H level can be suppressed.

### SECOND EMBODIMENT

Although an embodiment of the present invention has been described above, the present invention is not limited to the above-described embodiment and can be implemented in other embodiments as well.

FIG. 5 is a circuit diagram of an input buffer circuit according to the second embodiment of the present invention.

As shown in FIG. 5, an input buffer circuit 102 includes a differential amplifier circuit 50 and a control circuit 210. Control circuit 210 includes an inverter 2 and a coupled circuit 40.

The circuit arrangements of differential amplifier circuit 50 and inverter 2 are the same as those shown in FIG. 11 so that the description thereof will not be repeated.

Coupled circuit 40 includes a P-channel MOS transistor 41 and an N-channel MOS transistor 42 connected in series between a power-supply node VCC and a ground node 500. The gates of P-channel MOS transistor 41 and N-channel MOS transistor 42 are both connected to an output node A1 of differential amplifier circuit 50. In addition, an output node A4, which is a point where P-channel MOS transistor 41 and N-channel MOS transistor 42 are connected, is connected to output node A1 of differential amplifier circuit 50. Output node A4 is further connected to gates of a P-channel MOS transistor 8 and an N-channel MOS transistor 9 in inverter 2.

The threshold voltage of coupled circuit 40 is set to be equal to a threshold voltage Vth1 of inverter 2.

An operation of coupled circuit 40 in a case where a direct-current component of an input signal Vin and reference potential Vref fluctuate in common phase in input buffer circuit 102 having the above-described circuit arrangement will first be described.

An output signal Vout2 is output as a result of direct-current component V1 of input signal Vin1 and reference potential Vref input to differential amplifier circuit 50 rising to V2 as shown in FIG. 13.

Output signal Vout2 is supplied to the respective gates of P-channel MOS transistor 41 and N-channel MOS transistor 42 in coupled circuit 40. Consequently, P-channel MOS transistor 41 is turned on, and N-channel MOS transistor 42 is turned off. Thus, a potential is supplied from a power-supply node VCC to output node A4 until the potential level of the direct-current component of output signal Vout2 becomes equal to threshold voltage Vth1, and as a result, the potential at output node A4 rises.

On the other hand, when direct-current component V1 of input signal Vin1 and reference potential Vref input to differential amplifier circuit 50 drop to V3 as shown in FIG. 13 and an output signal Vout3 is output, P-channel MOS transistor 41 is turned off, while N-channel MOS transistor 42 is turned on in coupled circuit 40. Consequently, the potential at output node A4 is lowered until the potential level of output signal Vout3 becomes equal to threshold voltage Vth1.

As a result, a direct-current component of a signal φD output from coupled circuit 40 becomes substantially equal to threshold voltage Vth1 of inverter 2 even when direct-current component V1 of input signal Vin1 and reference potential Vref fluctuate. Thus, as compared to signal φB1 output from inverter 2 when input buffer circuit 101 receives input signal Vin1 at differential amplifier circuit 50, the shift in the timing at which signal φB2, which is output from inverter 2 when input buffer circuit 102 receives input signal Vin2 at differential amplifier circuit 50, or signal φB3, which is output from inverter 2 when input buffer circuit 102 receives input signal Vin3 at differential amplifier circuit 50, switches from the H level to the L level and the shift in the timing at which signal φB2 or signal φB3 switches from the L level to the H level are eliminated.

Now, in input buffer circuit 102 shown in FIG. 5, the operation of coupled circuit 40 when an amplitude of an input signal Vin fluctuates will be described.

In a case where the amplitude of input signal Vin1 input to differential amplifier circuit 50 is amplified, resulting in an input signal Vin4 which is input and an output signal Vout4 is output as a result, when the amplitude of output signal Vout4 is at the H level, P-channel MOS transistor 41 in coupled circuit 40 is turned off, and N-channel MOS transistor 42 is turned on. Consequently, the potential of output node A4 is lowered until the potential level of output signal Vout4 becomes equal to threshold voltage Vth1. On the other hand, when the amplitude of output signal Vout4 is at the L level, P-channel MOS transistor 41 is turned on, while N-channel MOS transistor 42 is turned off. Consequently, the potential of output node A4 rises until the potential level of output signal Vout4 becomes equal to threshold voltage Vth1.

Thus, the amplitude of a signal φD output from output node A4 by coupled circuit 40 having received output signal Vout4 approaches threshold voltage Vth1 when compared with the amplitude of output signal Vout4.

Similarly, in the case where the amplitude of input signal Vin1 input to differential amplifier circuit 50 is decreased, resulting in an input signal Vin5, and when input signal Vin5 is input and output signal Vout5 is output, the amplitude of signal φD output from output node A4 by coupled circuit 40 having received output signal Vout5 decreases, approaching threshold voltage Vth1.

According to the above-described operation, in a case where coupled circuit 40 receiving output signal Vout dynamically changes the impedance, thereby causing a direct-current component and an amplitude of input signal Vin to fluctuate, signal φB output from inverter 2 is not influenced by such fluctuations, and the timing at which signal φB switches from the H level to the L level and the timing at which signal φB switches from the L level to the H level would always be constant.

### THIRD EMBODIMENT

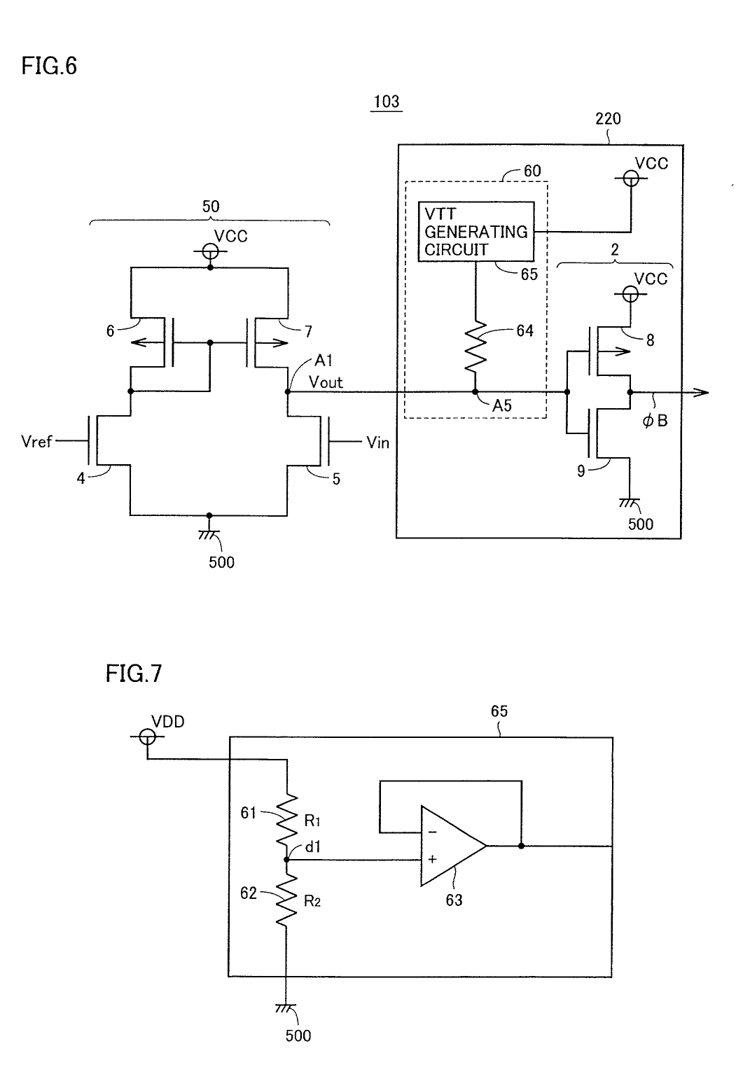

FIG. 6 is a circuit diagram of an input buffer circuit 103 according to the third embodiment of the present invention.

As shown in FIG. 6, input buffer circuit 103 includes a differential amplifier circuit 50 and a control circuit 220. In addition, control circuit 220 includes an inverter 2 and a coupled circuit 60.

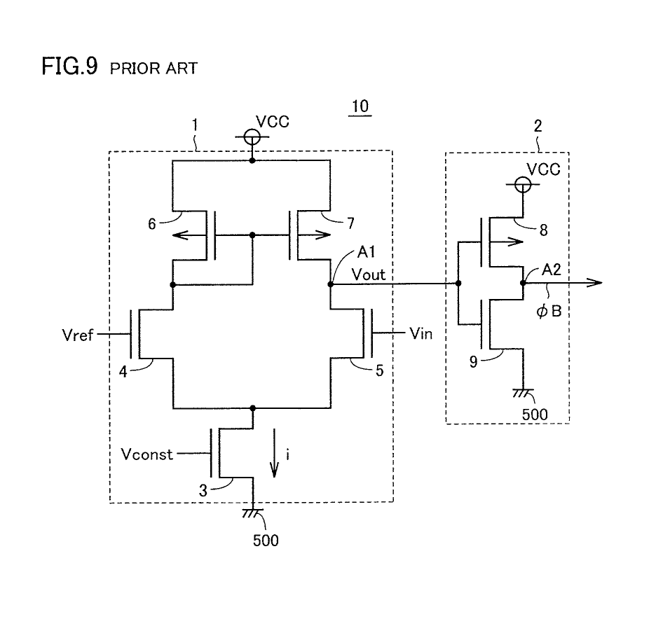

The circuit arrangements of differential amplifier circuit 50 and inverter 2 are the same as those shown in FIG. 9 so that the description thereof will not be repeated.

Coupled circuit 60 includes a constant potential (hereinafter referred to as VTT) generating circuit 65 and a resistance element 64. VTT generating circuit 65 is connected between a power-supply node VCC and resistance element 64. The other end of resistance element 64 is connected to an output node A1 and a common gate of a P-channel MOS transistor 8 and an N-channel MOS transistor 9 in inverter 2.

FIG. 7 is a circuit diagram of VTT generating circuit 65 shown in FIG. 6.

As shown in FIG. 7, the VTT generating circuit includes resistance elements 61 and 62 and an operational amplifier 63. Resistance elements 61 and 62 are connected in series between a power-supply node VDD and a ground node 500. Operational amplifier 63 functions as a voltage follower. Thus, operational amplifier 63 has a non-inverting input terminal connected to a node d1 which is a point where resistance elements 61 and 62 are connected, and has an output terminal connected to its inverting input terminal.

Coupled circuit 60 functions to supply a node A5 with a constant potential equal to threshold voltage Vth1 of inverter 2. Moreover, a resistance value of resistance element 64 is set equal to channel resistance values of a P-channel MOS transistor 7 and an N-channel MOS transistor 5.

An operation of coupled circuit 60 when a direct-current component of an input signal Vin and reference potential Vref fluctuate in common phase in input buffer circuit 103 having the above-described circuit arrangement will first be described.

An output signal Vout3 is output as a result of direct-current component V1 of input signal Vin1 and reference potential Vref input to differential amplifier circuit 50 dropping to V3 as shown in FIG. 13.

The potential of output signal Vout3 is greater than a potential Vth1 supplied to node A5 by coupled circuit 60. Thus, a current that flows through P-channel MOS transistor 7 of differential amplifier circuit 50 flows into resistance element 64, and consequently, the current that flows through N-channel MOS transistor 5 is reduced. As a result, output signal Vout2 output from output node A1 of differential amplifier circuit 50 is lowered, thus approaching threshold voltage Vth1 of inverter 2.

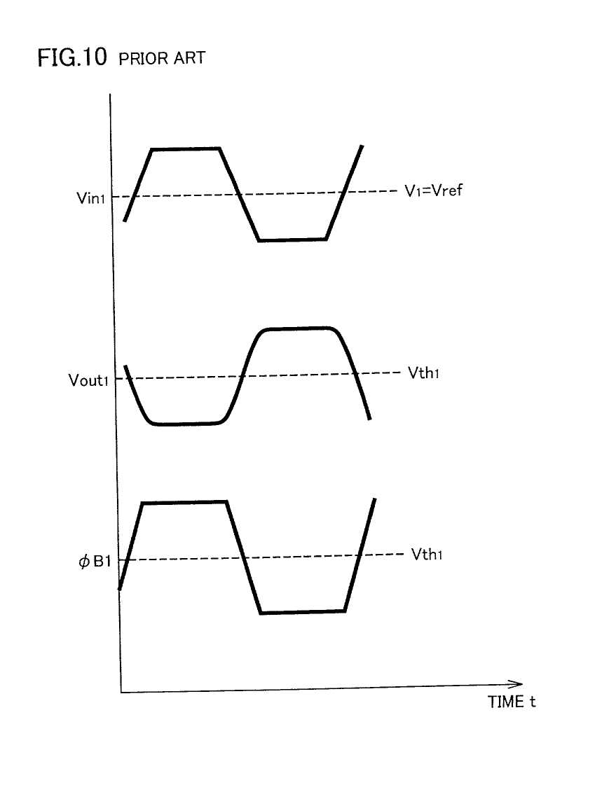

On the other hand, in a case where direct-current component V1 of input signal Vin1 and reference potential Vref input to differential amplifier circuit 50 rises to V2 as shown in FIG. 10 and thus output signal Vout2 is output, a current flows into N-channel MOS transistor 5 in differential amplifier circuit 50 from coupled circuit 60, whereby output signal Vout2 rises, thus approaching threshold voltage Vthl of inverter 2.

As a result, a direct-current component Vth1 of output signal Vout1 would remain substantially constant owing to coupled circuit 60 even when direct-current component V1 of input signal Vin1 and reference potential Vref fluctuate.

Now, in input buffer circuit 103 shown in FIG. 6, the operation of coupled circuit 60 when the amplitude of an input signal Vin fluctuates will be described.

In a case where the amplitude of input signal Vin1 input to differential amplifier circuit 50 is amplified, resulting in an input signal Vin4 which is input and an output signal Vout4 is output as a result, when the amplitude of output signal Vout4 is at the H level, a current that flows through P-channel MOS transistor 7 of differential amplifier circuit 50 flows into resistance element 64, and consequently the current that flows through N-channel MOS transistor 5 is reduced. On the other hand, when the amplitude of output signal Vout4 is at the L level, a current flows into N-channel MOS transistor 5 in differential amplifier circuit 50 from coupled circuit 60. As a result, the amplitude of output signal Vout4 decreases.

Similarly, in a case where the amplitude of input signal Vin1 input to differential amplifier circuit 50 is decreased, resulting in an input signal Vin5 which is input and an output signal Vout5 is output, when output signal Vout5 passes through output node A3 of coupled circuit 60, the amplitude of output signal Vout5 decreases, approaching threshold voltage Vth1.

According to the above-described operation, by having coupled circuit 60 function as a constant potential generating circuit, it becomes possible to output from inverter 2 a signal φB that is not influenced by the fluctuations of a direct-current component of input signal Vin and of reference potential Vref and the fluctuation in the amplitude of input signal Vin.

Thus, the timing at which signal φB switches from the H level to the L level and the timing at which signal φB switches from the L level to the H level would always be constant.

### FOURTH EMBODIMENT

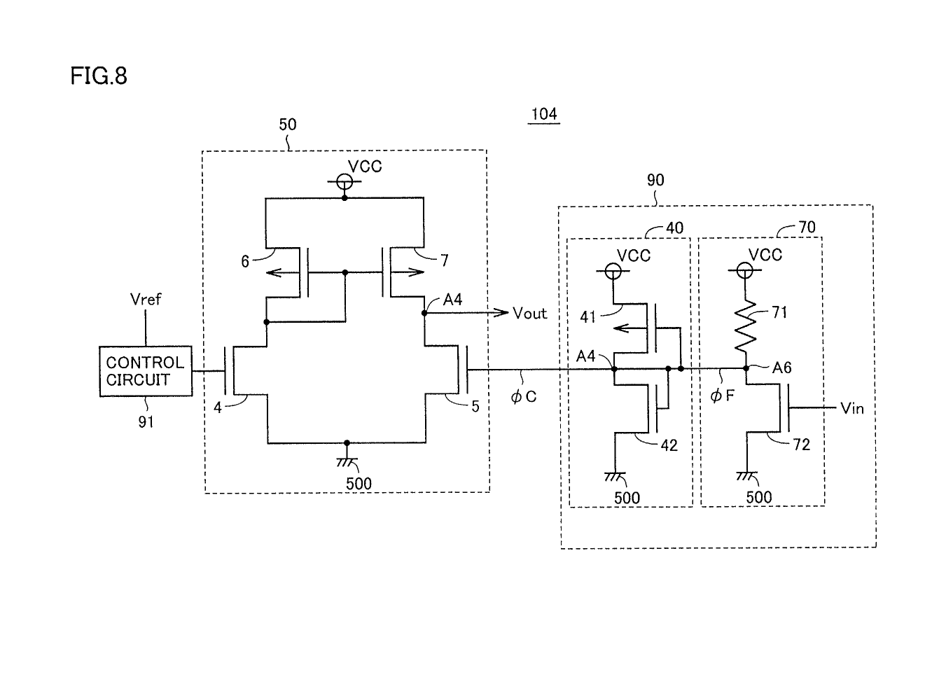

FIG. 8 is a circuit diagram of an input buffer circuit 104 according to the fourth embodiment of the present invention.

As shown in FIG. 8, input buffer circuit 104 includes a differential amplifier circuit 50 and control circuits 90 and 91. Moreover, control circuit 90 includes an inverting amplifier circuit 70 and a coupled circuit 40.

Inverting amplifier circuit 70 includes a resistance element 71 and an N-channel MOS transistor 72. Resistance element 71 is connected between a power-supply node VCC and an output node A6, and N-channel MOS transistor 72 is connected between output node A6 and a ground node 500. Inverting amplifier circuit 70 in which N-channel MOS transistor 72 receives an input signal Vin1 at a gate inverts input signal Vin and amplifies the amplitude of the signal.

Coupled circuit 40 includes a P-channel MOS transistor 41 and an N-channel MOS transistor 42 connected in series between a power-supply node VCC and a ground node 500. The gates of P-channel MOS transistor 41 and N-channel MOS transistor 42 are both connected to an output node A6 of inverting amplifier circuit 70. In addition, an output node A4, which is a point where P-channel MOS transistor 41 and N-channel MOS transistor 42 are connected, is connected to a gate of an N-channel MOS transistor 5 in differential amplifier circuit 50.

Coupled circuit 40 may have the same circuit arrangement as that of coupled circuit 30 shown in FIG. 2 or coupled circuit 60 shown in FIG. 6.

The circuit arrangement of control circuit 91 is the same as that of control circuit 90. Reference potential Vref is input to control circuit 91 and control circuit 91 outputs a signal to an N-channel MOS transistor 4 in differential amplifier circuit 50.

The circuit arrangement of differential amplifier circuit 50 is the same as that shown in FIG. 9 so that the description thereof will not be repeated.

An operation of control circuit 90 when a direct-current component of input signal Vin and reference potential Vref fluctuate in common phase in input buffer circuit 104 having the above-described circuit arrangement will first be described.

When direct-current component V1 of input signal Vin1 and reference potential Vref rise to V2 as shown in FIG. 13, resulting in an input signal Vin2, a direct-current component VF2 of a signal φF2 output from inverting amplifier circuit 70 having received input signal Vin2 becomes smaller than a direct-current component VF1 of a signal φF1 output from inverting amplifier circuit 70 receiving input signal Vin1.

Signal φF2 is supplied to the respective gates of P-channel MOS transistor 41 and N-channel MOS transistor 42 in coupled circuit 40. As a result, P-channel MOS transistor 41 is turned on and N-channel MOS transistor 42 is turned off. Consequently, a potential is supplied from power-supply node VCC to output node A4, and the potential of output node A4 rises.

On the other hand, when direct-current component V1 of input signal Vin1 and reference potential Vref drop to V3, resulting in input signal Vin3, P-channel MOS transistor 41 in coupled circuit 40 is turned off, while N-channel MOS transistor 42 is turned on. Consequently, the potential of output node A4 is lowered.

The operation of control circuit 91 when a direct-current component of input signal Vin and reference potential Vref fluctuate in common phase in input buffer circuit 104 is the same as described above so that the description will not be repeated.

As a result, a direct-current component of the signals output from control circuits 90 and 91 would become substantially constant even when direct-current component V1 of input signal Vin1 and reference potential Vref fluctuate. Thus, the shift in the timing at which output signal Vout, which is output from an output node when input buffer circuit 104 receives input signal Vin at differential amplifier circuit 50, switches from the H level to the L level and the shift in the timing at which output signal Vout switches from the L level to the H level are eliminated.

Now, in input buffer circuit 104 shown in FIG. 8, the operation of control circuit 90 when the amplitude of an input signal Vin fluctuates will be described.

When the amplitude of input signal Vin fluctuates, the amplitude increases in inverting amplifier circuit 70. As a result, the slew rate of signal φF output from inverting amplifier circuit 70 becomes faster than the slew rate of input signal Vin1. The amplified signal φF is input to coupled circuit 40. When the amplitude of signal φF is at the H level, P-channel MOS transistor 41 in coupled circuit 40 is turned off and N-channel MOS transistor 42 is turned on. Thus, the potential level of signal φF is lowered. On the other hand, when the amplitude of signal φF is at the L level, P-channel MOS transistor 41 is turned on and N-channel MOS transistor 42 is turned off. Consequently, the potential level of signal φF rises.

Thus, when signal φF passes through output node A4 of coupled circuit 40, the amplitude of an output signal φC decreases.

According to the above-described operation, it becomes possible to increase the operation speed of differential amplifier circuit 50 by first increasing the amplitude of input signal Vin with inverting amplifier circuit 70 in control circuit 90, thereby making the slew rate faster, and thereafter, by decreasing the amplitude of coupled circuit 40.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An input buffer circuit, comprising:
a differential amplifier circuit for comparing a potential of an input signal input to a first differential input node with a reference potential input to a second differential input node and for outputting an output signal from an output node;
an inverter; and
a coupling circuit for approximating a potential level of a direct-current component of the output signal output from the output node of said differential amplifier circuit to a logic threshold value of said inverter and for outputting said output signal to said inverter.

2. The input buffer circuit according to claim 1, wherein said coupling circuit decreases an amplitude of the output signal output from the output node of said differential amplifier circuit and outputs said output signal to said inverter.

3. The input buffer circuit according to claim 2, wherein said coupling circuit includes a constant potential generating circuit for generating a constant potential and supplying the constant potential to the output node of said differential amplifier circuit.

4. The input buffer circuit according to claim 3, wherein said constant potential generating circuit includes
a first transistor connected between the output node of said differential amplifier circuit and a power-supply node, and
a second transistor connected between the output node of said differential amplifier circuit and a ground node.

5. The input buffer circuit according to claim 4, wherein substantially equal potentials are supplied to gates of said first transistor and said second transistor.

6. The input buffer circuit according to claim 4, wherein gates of said first transistor and said second transistor are connected to the output node of said differential amplifier circuit.

7. An input buffer circuit, comprising:
a first coupling circuit for approximating a potential level of a direct-current component of an input signal to a prescribed potential level and for outputting said input signal;
a second coupling circuit for approximating a potential level of a direct-current component of a reference potential to a prescribed potential level and for outputting said reference potential; and
a differential amplifier circuit for comparing a potential of the input signal output from said first coupling circuit and input to a first differential input node with the reference potential output from said second coupling circuit and input to a second differential input node and for outputting an output signal from an output node.

8. The input buffer circuit according to claim 7, wherein
said first coupling circuit decreases an amplitude of said input signal and outputs said input signal to the first differential input node of said differential amplifier circuit, and
said second coupling circuit decreases an amplitude of said reference potential and outputs said reference potential to the second differential input node of said differential amplifier circuit.

9. The input buffer circuit according to claim 8, further comprising:
a first inverting amplifier circuit for amplifying said input signal and outputting an amplified signal to said first coupling circuit; and
a second inverting amplifier circuit for amplifying said reference potential and outputting an amplified reference potential to said second coupling circuit.

10. The input buffer circuit according to claim 8, wherein
said first coupling circuit includes a first constant potential generating circuit for generating a first constant potential and supplying the first constant potential to the first differential input node of said differential amplifier circuit, and
said second coupling circuit includes a second constant potential generating circuit for generating a second constant potential and supplying the second constant potential to the second differential input node of said differential amplifier circuit.

11. The input buffer circuit according to claim 10, wherein said first constant potential generating circuit includes
a first transistor connected between the first differential input node of said differential amplifier circuit and a power-supply node, and
a second transistor connected between the first differential input node of said differential amplifier circuit and a ground node, and wherein said second constant potential generating circuit includes
a third transistor connected between the second differential input node of said differential amplifier circuit and a power-supply node, and
a fourth transistor connected between the second differential input node of said differential amplifier circuit and a ground node.

12. The input buffer circuit according to claim 11, wherein substantially equal potentials are supplied to gates of said first to fourth transistors.

13. The input buffer circuit according to claim 11, wherein
gates of said first transistor and said second transistor are connected to the first differential input node of said differential amplifier circuit, and
gates of said third transistor and said fourth transistor are connected to the second differential input node of said differential amplifier circuit.
